(19) United States
(12) Patent Application Publication
(10) Pub. No.: US 2013/0153280 A1
(43) Pub. Date: Jun. 20, 2013

(54) PRINTED CIRCUIT BOARD AND METHOD OF MANUFACTURING THE SAME

(71) Applicants: Sang Hoon Kim, Gyunggi-do (KR); Going Sik Kim, Yongin-si (KR)

(72) Inventors: Sang Hoon Kim, Gyunggi-do (KR); Going Sik Kim, Yongin-si (KR)

(73) Assignee: SAMSUNG ELECTRO-MECHANICS CO., LTD., Gyunggi-do (KR)

(21) Appl. No.: 13/425,622

(22) Filed: Mar. 21, 2012

(30) Foreign Application Priority Data
Dec. 19, 2011 (KR) 1020110137296

(51) Int. Cl. H05K 1/11; H05K 3/02; H05K 3/40; H05K 3/10

(52) U.S. Cl. 174/262; 29/846; 29/847

(57) ABSTRACT

Disclosed herein is a printed circuit board including: a substrate; first upper and lower insulating layers covering upper and lower sides of the substrate; a via penetrating the substrate and the first upper and lower insulating layers to form an electrical connection; and second upper and lower insulating layers covering or surrounding the via, wherein the first upper and lower insulating layers or the second upper and lower insulating layers include a general circuit region including general circuit patterns and circuit patterns connected to the via and a microcircuit region including microcircuit patterns having a smaller circuit line width than that of the general circuit region.

### CROSS REFERENCE TO RELATED APPLICATION

This application claims the benefit of Korean Patent Application No. 10-2011-0137296, filed Dec. 19, 2011, entitled “Printed circuit board and manufacturing method thereof”, which is hereby incorporated by reference in its entirety into this application.

### BACKGROUND OF THE INVENTION

1. Technical Field

The present invention relates a printed circuit board and a method of manufacturing the same.

2. Description of the Related Art

Recently, in order to keep up with the densification of semiconductor chips and the increase of signal transfer speed, a technology of directly mounting a semiconductor chip in a substrate has been increasingly required. Therefore, it is also required to develop a high-density and high-reliability substrate which can cope with the densification of semiconductor chips.

The required specifications of a high-density and high-reliability substrate are closely related to the specifications of a semiconductor chip, and have many problems to be solved, such as the miniaturization of circuits, excellent electrical properties, high-speed signal transmission, high reliability, high functionality and the like. In order to solve these problems, technologies for forming a microcircuit pattern and a microvia hole in a printed circuit board are required.

Generally, as disclosed in Korean Unexamined Patent Publication No. 2007-0109264 (2007 Nov. 15), examples of methods of forming a circuit pattern of a printed circuit board include a subtractive process, a full additive process, a semi-additive process and the like. Among these processes, currently, a semi-additive process which can miniaturize a circuit pattern is attracting considerable attention.

However, the circuit pattern formed by a semi-additive process is problematic in that it is separated from an insulation layer because it is formed on the insulation layer by embossing. Particularly, as a circuit pattern is gradually miniaturized, the contact area between an insulation layer and a circuit pattern is decreased, and thus the adhesion therebetween becomes low, so that the circuit pattern is more easily separated from the insulation layer, and particularly, in the case of a multi-layered printed circuit board, when a circuit pattern is separated from an insulation layer, the reliability thereof is remarkably deteriorated.

Recently, in order to overcome the above problems, new methods have been proposed. Among these new methods, an LPP (Laser Patterning Process), in which a circuit pattern is formed by forming a trench on an insulation layer using a laser and then plating, grinding and etching the trench, has attracted considerable attention.

When a printed circuit board is manufactured by the conventional LPP, there is an advantage in that it is possible to prevent a circuit pattern from being separated from an insulation layer because the circuit pattern is buried therein.

However, in the conventional LPP, the trenches in a microcircuit region having a small circuit width and a general circuit region having a large circuit width are plated, and then a grinding process must be additionally conducted in order to flatten the plated layer. Further, in the conventional LPP, both a trench circuit and via holes are plated, and a grinding process must be additionally conducted.

Therefore, the method of manufacturing a printed circuit board using the conventional LPP is problematic in that a plated layer or a substrate may be damaged because it is difficult to control the additional grinding process.

### SUMMARY OF THE INVENTION

Accordingly, the present invention has been devised to solve the above-mentioned problems, and the present invention intends to provide a method of manufacturing a printed circuit board, in which different working processes are used according to the kind of circuit regions including a microcircuit region and a general circuit region, and in which a grinding process is not required.

Further, the present invention intends to provide a printed circuit board including a microcircuit pattern region and a general circuit region on the same layer, which is manufactured using the method.

An aspect of the present invention provides a printed circuit board, including: a substrate; first upper and lower insulating layers covering upper and lower sides of the substrate; a via penetrating the substrate and the first upper and lower insulating layers to form an electrical connection; and second upper and lower insulating layers covering or surrounding the via, wherein the first upper and lower insulating layers or the second upper and lower insulating layers include a general circuit region including general circuit patterns and circuit patterns connected to the via and a microcircuit region including microcircuit patterns having a smaller circuit line width than that of the general circuit region.

The printed circuit board may further include: a bump disposed on the microcircuit pattern of the microcircuit region, wherein the bump is surrounded by the second upper and lower insulating layers.

In the printed circuit board, the microcircuit pattern including the bump may be provided on one side thereof with a post.

Another aspect of the present invention provides a method of manufacturing a printed circuit board, including: forming inner circuits on upper and lower sides of a substrate and then forming a first via connecting with parts of the inner circuits; forming first insulating layers covering the inner to circuits and the first via; forming a second via connected to the first via and penetrating the first insulating layers, a general circuit region including general circuit patterns and circuit patterns connected to the second via, and a microcircuit region including a plurality of microcircuit patterns; and forming second insulating layers covering the first insulating layers.

In the method, the inner circuits may be formed by a SAP (semi-additive process), an MSAP (modified semi-additive process) or a subtractive process.

In the method, the forming of the circuit region may include: forming a plurality of trenches on outer surfaces of the first insulating layers; forming an upper blind via hole (BVH) for exposing an upper surface of the first via and/or a lower blind via hole (BVH) for exposing a lower surface of the first via; and forming the microcircuit pattern and a second via by charging the trenches and the upper and lower BVHs with an electroconductive metal.

In the method, in the forming of the second insulation layers, the bump formed on a part of the microcircuit pattern may be surrounded by the second insulation layer.

In the method, a part of the microcircuit pattern provided with the bump may be formed into a post.

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a sectional view showing a printed circuit board according to an embodiment of the present invention;

FIGS. 2A to 2H are sectional views explaining a method of manufacturing a printed circuit board according to an embodiment of the present invention; and

FIG. 3 is a sectional view showing a printed circuit board according to another embodiment of the present invention.

### DESCRIPTION OF THE PREFERRED EMBODIMENTS

The objects, features and advantages of the present invention will be more clearly understood from the following detailed description of preferred embodiments taken in conjunction with the accompanying drawings. Throughout the accompanying drawings, the same reference numerals are used to designate the same or similar components, and redundant descriptions thereof are omitted. Further, in the following description, the terms “first”, “second” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

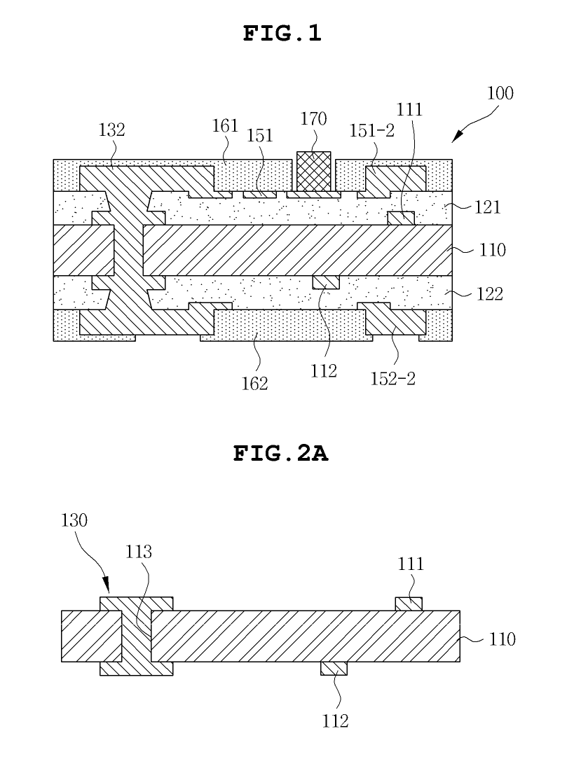

Hereinafter, preferred embodiments of the present invention will be described in detail with reference to the attached drawings. FIG. 1 is a sectional view showing a printed circuit board according to an embodiment of the present invention

As shown in FIG. 1, the printed circuit board 100 according to an embodiment of the present invention includes: a substrate 110; first insulating layers 121 and 122 covering upper and lower sides of the substrate 110; a via 132 penetrating the substrate 110 and the first insulating layers 121 and 122 to form a circuit; a second upper insulating layer 161 covering an upper portion of the via 132, an upper microcircuit pattern 151 and an upper general circuit pattern 151-2; a second lower insulating layer 162 surrounding a lower portion of the via 132 and a lower general circuit pattern 152-2; and a bump 170 disposed on the upper microcircuit pattern 151 and surrounded by the second upper insulating layer 161.

The substrate 110 serves to support the printed circuit board 100, and may be made of a high-strength insulating material or a metal. Meanwhile, when the substrate 110 is made of a metal in order to increase a heat radiation effect, an insulating film may be additionally provided such that the substrate 110 is insulated from the via 132 and inner circuits.

The via 132 is formed to electrically connect the inner circuits formed on the upper and lower sides of the substrate 110 with each other or electrically connect the general circuit patterns or microcircuit patterns formed on the first insulating layers 121 and 122 with each other. The via 132 and the inner circuit may be made of an electroconductive metal such as gold, silver, nickel, copper or the like.

The inner circuits are formed on both sides of the substrate 110. As shown in FIG. 1, the inner circuits are formed on both sides of the substrate 110, but the inner circuits may be formed only on one side thereof. Here, since the inner circuits are buried in the first insulating layers 121 and 122, an undercut, which has occurred in conventional microcircuits, does not occur. Further, the inner circuits may be electrically connected with outer circuits by the via 132.

The first insulating layers 121 and 122 are classified into a first upper insulating layer 121 and a first lower insulating layer 122. The first upper insulating layer 121 is provided on the outer surface thereof with an upper microcircuit region including the upper microcircuit pattern 151 and a general circuit region including a general circuit pattern, and the first lower insulating layer 122 is provided on the outer surface thereof with a lower microcircuit region including the lower microcircuit pattern 152 and a general circuit region including a general circuit pattern.

The second upper insulating layer 161 and the second lower insulating layer 162 are formed to cover the first upper insulating layer 121 and the first lower insulating layer 122 using a solder resist, respectively. In particular, the second upper insulating layer 161 is formed to surround the bump 170 disposed on the upper microcircuit pattern 151.

The printed circuit board 100 according to an embodiment of the present invention, configured in this way, may be provided on the same layer with a general circuit region including the inner circuits connected to the via 132 and the general circuit pattern 151-2 and a microcircuit region including the upper microcircuit pattern 151.

That is, the general circuit region including the inner circuits connected to the via 132 and the general circuit pattern 151-2 is a region having a circuit line width of more than 10 μm, and the microcircuit region including the upper microcircuit pattern 151 is a region having a smaller circuit line width than that of the general circuit region.

As shown in FIG. 1, both the general circuit region and the microcircuit region can be provided on the same layer such as the first upper insulating layer 121 or the first lower insulating layer 122.

Therefore, the printed circuit board 100 according to an embodiment of the present invention includes the general circuit region and the microcircuit region, and each of the regions may be processed using a different method.

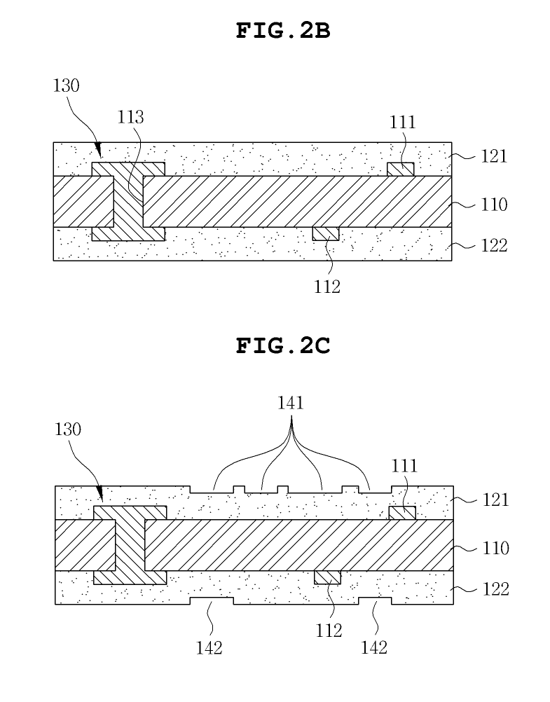

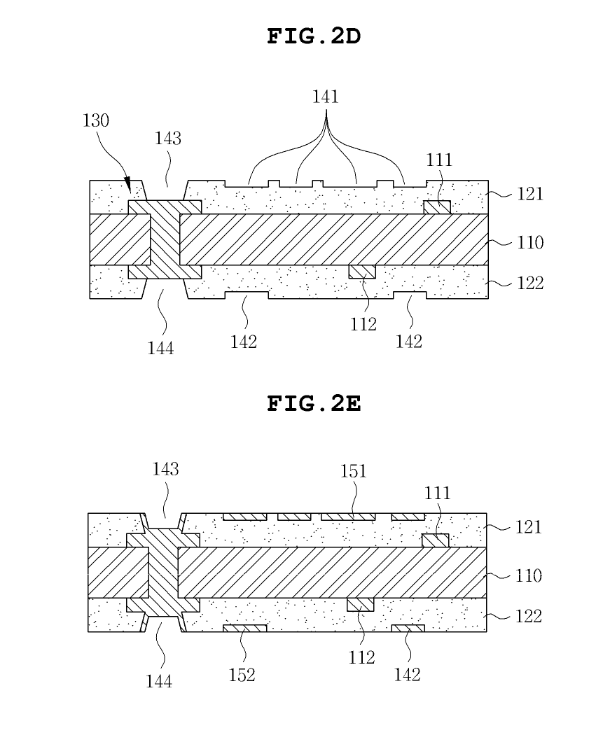

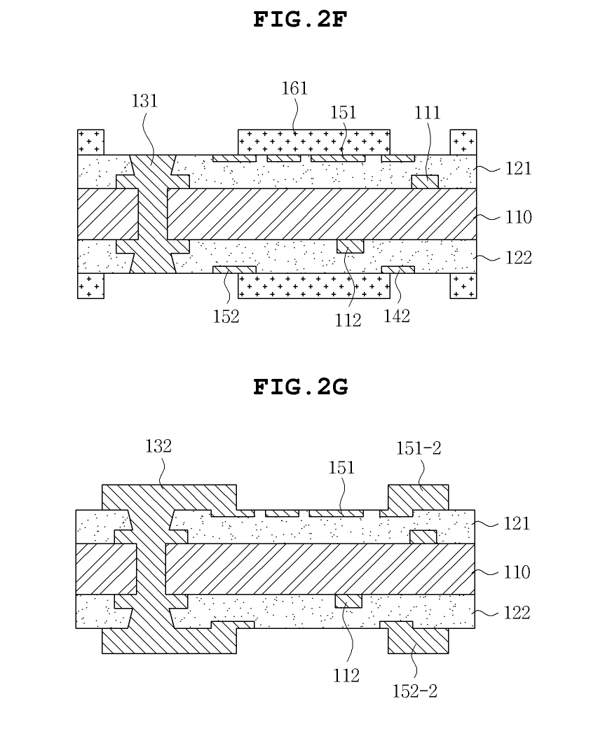

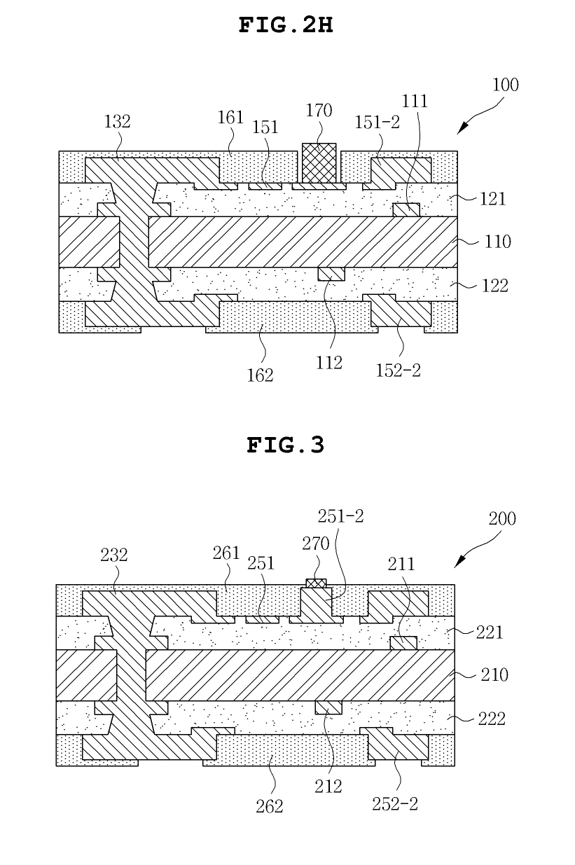

Hereinafter, a method of manufacturing a printed circuit board according to an embodiment of the present invention will be described with reference to FIGS. 2A to 2H. FIGS. 2A to 2H are sectional views explaining a method of manufacturing a printed circuit board according to an embodiment of the present invention.

First, as shown in FIG. 2A, in the method of manufacturing a printed circuit board according to an embodiment of the present invention, inner circuits 111 and 112 are formed on upper and lower sides of a substrate 110, and a first via 130 connecting with parts of the inner circuits 111 and 112 through a via hole 113 is formed. In this case, the via hole 113 may be formed by laser processing using a CO₂ laser or drilling.

The first via 130 may be formed by charging and plating the via hole 113 with an electroconductive metal such as gold, silver, nickel, copper or the like. The inner circuits 111 and 112 may also be formed by plating.

That is, the first via 130 and the inner circuits 111 and 112 including an upper inner circuit pattern and a lower inner circuit pattern may be formed using a general SAP (semi-additive process), an MSAP (modified semi-additive process), a subtractive process or the like. Here, since the inner circuits 111 and 112 are formed using the SAP or the like, problems with interlayer matching do not occur, and manufacturing cost can be reduced compared to a conventional LPP.

After the inner circuits 111 and 112 are formed on the upper and lower sides of the substrate 110, as shown in FIG. 2B, a first upper insulating layer 121 and a first lower insulating layer 122 are formed on the upper and lower sides of the substrate 110 to cover the inner circuits including the via to 130.

The first upper insulating layer 121 and the first lower insulating layer 122 are made of a thermosetting resin.

After the first upper insulating layer 121 and the first lower insulating layer 122 are formed, as shown in FIG. 2C, a plurality of trenches 141 and 142 for forming microcircuit patterns are formed on the exposed surfaces of the first upper insulating layer 121 and the first lower insulating layer 122, respectively.

Concretely, the plurality of trenches 141 and 142 may be formed in the same size as the line width of a microcircuit pattern using a CO₂ laser or an excimer laser, and may be formed on the exposed surfaces of the first upper insulating layer 121 and the first lower insulating layer 122 with smaller width and depth than the line width (10 μm) of the following general circuit region.

Subsequently, as shown in FIG. 2D, an upper blind via hole (BVH) 143 for exposing the upper surface of the first via 130 and a lower blind via hole (BVH) 144 for exposing the lower surface of the first via 130 are formed. Here, the upper BVH 143 and the lower BVH 144 may be formed by laser processing, drilling, imprinting or the like.

After the upper BVH 143 and the lower BVH 144 are formed, as shown in FIG. 2E, the plurality of trenches and the upper and lower BVHs 143 and 144 are plated.

Here, the process of plating the plurality of trenches 141 and 142 and the upper and lower BVHs 143 and 144 are conducted until an electroconductive metal such as gold, silver, nickel, copper or the like is charged and buried in the plurality of trenches 141 and 142. In this case, when the plurality of trenches 141 and 142 are excessively plated with the electroconductive metal, the excessively plated portion may be additionally etched.

Thus, electroplated layers made of an electroconductive metal are formed on the inner sides of BVHs 143 and 144, and the plurality of trenches 141 and 142 are also charged with the electroconductive metal to form microcircuit patterns 151 and 152. Here, since the microcircuit patterns 151 and 152 are formed to such a degree that the electroconductive metal is buried in the trenches 141 and 142, it is not required to conduct a conventional grinding process.

Subsequently, as shown in FIG. 2F, photoresist patterns 161 for covering parts of the microcircuit patterns 151 and 152 are formed, and the BVHs 143 and 144 are charged with the electroconductive metal to form a second via 131.

Concretely, the second via 131 may be formed by charging the BVHs 143 and 144 with the electroconductive metal using the electroplated layers formed on the inner sides of the BVHs 143 and 144 as seed layers.

The photoresist patterns 161 covering parts of the microcircuit patterns 151 and 152 are used to form a final via 132 using the second via 132.

When the plating process is further conducted using the photoresist patterns 161, and, as shown in FIG. 2G, a final via 132 and general outer circuit patterns 151-2 and 152-2 connected to the via 132 are formed.

Subsequently, a lift-off process and a cleaning process are conducted to remove the photoresist patterns 161.

The via 132 formed in this way penetrates the substrate 110 and the first insulating layers 121 and 122 to connect inner circuits with outer circuits to form a circuit, and may be connected to parts of the microcircuit patterns 151 and 152.

After the final via 132 and the outer circuit patterns 151-2 and 152-2 are formed, as shown in FIG. 2H, a second upper insulating layer 161 for covering the first upper insulating layer 121 and a second lower insulating layer 162 for covering the first lower insulating layer 122 are formed.

Concretely, the second upper insulating layer 161 is formed to cover the upper portion of the via 132 and the upper microcircuit patterns 151 and 151-2, and the second lower insulating layer 162 is formed to surround the lower portion of the via 132 and the lower microcircuit patterns 152 and 152-2.

In this case, a part of the second insulating layer 161 is etched to expose a part of the upper microcircuit pattern 151, and a bump 170 is formed on the exposed upper microcircuit pattern 151. The bump 170 may also be formed on a part of the lower microcircuit pattern 152.

The bump 170 may be formed by printing an electroconductive metal paste such as gold, silver, nickel, copper or the like on a part of the upper microcircuit pattern 151. Here, the bump 170 may also be formed by plating in addition to printing the electroconductive metal paste.

As such, in the method of manufacturing a printed circuit board 100 according to an embodiment of the present invention, a general circuit region including the general inner circuit patterns connected to the via 132 and the general outer circuit patterns and a microcircuit region including the upper microcircuit pattern may be provided on the same layer.

Further, in the method of manufacturing a printed circuit board 100 according to an embodiment of the present invention, since the general circuit region and the microcircuit region are separately formed, microcircuit patterns having uniform thickness can be formed without performing a grinding process for decreasing the unevenness between regions.

Therefore, in the method of manufacturing a printed circuit board 100 according to an embodiment of the present invention, since the grinding process is omitted, the time and cost required to manufacture the printed circuit board 100 can be reduced.

Hereinafter, a printed circuit board 200 according to another embodiment of the present invention will be described with reference to FIG. 3. FIG. 3 is a sectional view showing a printed circuit board 200 according to another embodiment of the present invention.

This printed circuit board 200 is the same as the printed circuit board 100 shown in FIG. 1, except that a part of an upper microcircuit pattern 251 is plated with an electroconductive metal to form a post 251-2 protruding upwards.

Owing to the post 251-2, the amount of a bump 270 to be disposed on the post 251-2 can be decreased, and thus other components (not shown) can be mounted using the thin bump 270.

Therefore, in the printed circuit board 200 according to the other embodiment of the present invention, the manufacturing cost thereof can be reduced by decreasing the amount of the bump 270.

As described above, the printed circuit board according to the present invention is provided on the same layer with a general circuit region including the general inner circuit patterns connected to the via 132 and the general outer circuit patterns and a microcircuit region including the upper microcircuit pattern.

Further, according to the method of manufacturing a printed circuit board of the present invention, since a general circuit region and a microcircuit region including microcircuit patterns are separately formed, microcircuit patterns having uniform thickness can be formed without performing a grinding process for decreasing the unevenness between regions.

Furthermore, according to the method of manufacturing a printed circuit board of the present invention, since a grinding process is omitted, the time and cost required to manufacture the printed circuit board can be reduced.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A printed circuit board, comprising:
a substrate;
first upper and lower insulating layers covering upper and lower sides of the substrate;
a via penetrating the substrate and the first upper and lower insulating layers to form an electrical connection; and
second upper and lower insulating layers covering or surrounding the via,
wherein the first upper and lower insulating layers or the second upper and lower insulating to layers include a general circuit region including general circuit patterns and circuit patterns connected to the via, and a microcircuit region including microcircuit patterns having a smaller circuit line width than that of the general circuit region.

2. The printed circuit board according to claim 1, further comprising:
a bump disposed on the microcircuit pattern of the microcircuit region,
wherein the bump is surrounded by the second upper and lower insulating layers.

3. The printed circuit board according to claim 1, wherein the general circuit region and the microcircuit region are provided on the same layer.

4. The printed circuit board according to claim 1, wherein the substrate is provided on upper and lower sides thereof with inner circuits connected to the via.

5. The printed circuit board according to claim 1, wherein the general circuit region has a circuit line width of more than 10 μm, and a part of the microcircuit pattern of the microcircuit region is buried in the first insulating layer.

6. The printed circuit board according to claim 2, wherein the microcircuit pattern including the bump is provided on one side thereof with a post.

7. A method of manufacturing a printed circuit board, comprising:
forming inner circuits on upper and lower sides of a substrate and then forming a first via connecting with parts of the inner circuits;
forming first insulating layers covering the inner circuits and the first via;
forming a second via connected to the first via and penetrating the first insulating layers, a general circuit region including general circuit patterns and circuit patterns connected to the second via, and a microcircuit region including a plurality of microcircuit patterns; and
forming second insulating layers covering the first insulating layers.

8. The method according to claim 7, wherein the inner circuits are formed by a SAP (semi-additive process), an MSAP (modified semi-additive process) or a subtractive process.

9. The method according to claim 7, wherein the forming of the circuit region comprises:
forming a plurality of trenches on outer surfaces of the first insulating layers;
forming an upper blind via hole (BVH) for exposing an upper surface of the first via and/or a lower blind via hole (BVH) for exposing a lower surface of the first via; and
forming the microcircuit pattern and a second via by charging the trenches and the upper and lower BVHs with an electroconductive metal.

10. The method according to claim 9, wherein the plurality of trenches are formed using a laser.

11. The method according to claim 9, wherein the microcircuit pattern is formed by charging the trenches with the electroconductive metal, and the second via is formed by charging the BVHs with the electroconductive metal.

12. The method according to claim 9, wherein the forming of the second insulation layers comprises:
forming a final via connected with the second via and covered with the second insulating layers; and
forming the second insulating layers covering or surrounding the final via or the microcircuit pattern.

13. The method according to claim 7, wherein, in the forming of the second insulation layers, the bump formed on a part of the microcircuit pattern is surrounded by the second insulation layer.

14. The method according to claim 13, wherein a part of the microcircuit pattern provided with the bump is formed into a post.
